(19) United States
(12) Patent Application Publication
(10) Pub. No.: US 2012/0088072 A1
(43) Pub. Date: Apr. 12, 2012

(54) Microfabricated Particles in Composite Materials and Methods for Producing the Same

(76) Inventors: Adam R. Pawloski, Lake Elmo, MN (US); Jeffrey Jacob Cernohous, Hudson, WI (US)

(21) Appl. No.: 13/377,643

(22) PCT Filed: Jun. 11, 2010
(86) PCT No.: PCT/US10/38326

§ 371 Date: Dec. 12, 2011

Related U.S. Application Data
(60) Provisional application No. 61/186,653, filed on Jun. 12, 2009.
(60) Provisional application No. 61/262,651, filed on Nov. 19, 2009.

(51) Int. Cl. H01B 1/20; H01F 1/00; C08L 23/02; B05D 1/12; B29B 9/14; B29C 45/00; B29C 47/00; G03F 7/20; C08L 83/04

(52) U.S. Cl. 428/143; 430/8; 252/62.54; 252/500; 524/570; 524/588; 264/299; 264/328.1; 264/176.1; 427/180

(57) ABSTRACT

Microfabricated particles are dispersed throughout a matrix to create a composite. The microfabricated particles are engineered to a specific structure and composition to enhance the physical attributes of a composite material.

### CROSS REFERENCE TO RELATED APPLICATIONS

This application claims priority to U.S. Provisional Patent Application No. 61/186,653 filed Jun. 12, 2009 and U.S. Provisional Patent Application No. 61/262,651 flied Nov. 19, 2009, the disclosures of which are herein incorporated by reference in their entirety.

### TECHNICAL FIELD

The present invention relates to the application of microfabricated particles in a matrix composition. Specifically, the present invention is a microfabricated particle of a specific engineering design dispersed in a matrix to impart enhanced physical characteristics to the resulting composite material.

### BACKGROUND

Fiber-reinforced composite materials offer several advantages in physical properties over those of the matrix itself. Fiber reinforcement is often used to improve mechanical properties of the composite compared to the matrix alone. Mechanical strength, such as tensile, flexural, or impact strength, may be improved by the addition of fibers to the matrix, often with very favorable strength-to-weight ratios and cost benefits. One common implementation of fiber-reinforced composites is the addition of fiberglass to thermoplastic or thermoset polymers. Fibers may be made of synthetic polymers, natural polymers, metals, ceramics, inorganic materials, carbonized material, or other substances that are typically stiffer than the matrix material. Common fibers are drawn by solution or melt processing into continuous filaments, which may be further processed into thread, rope, fabric, or a weave. Fibers may be incorporated into composites using the continuous form of the fiber or by cutting the fiber down into short fiber pieces.

Alignment of fibers within the matrix has consequences on the physical properties of the composite. Fibers naturally have preferential tensile strength when strained along the long axis of the fiber. Accordingly, fiber-reinforced composites also exhibit preferential improvement in tensile strength when strained along the direction that fibers are aligned. Typically, the composite is much weaker in other directions that are not aligned with the fiber axis. Designs for composite products typically require layering fibers so that directionality of the fiber axis is varied across the layers, thus reducing the effects of anisotropy in mechanical strength. This requirement often complicates the design of products made from fiber reinforced composites and may limit the application of some materials. In addition, compressive strength of fiber-reinforced composites is typically poor because fibers may kink and buckle under compression.

### SUMMARY

There is great interest to further improve the mechanical properties of composites, particularly to address multidirectional forces applied to the composite. The composite reinforcement technology of the present invention will make use of microfabricated particles with engineered structure and composition to specifically address physical and chemical attributes of a composite material. The microfabricated particles are dispersed throughout a matrix to create the composite. For purposes of the invention, a microfabricated particle is a microfabricated object disperseable in a matrix wherein the object is of a predetermined design addressing its structure and composition. The microfabricated particle is included to impart a desired physical characteristic to the composite. The application of the microfabricated particle often results in isotropic physical enhancements in the composite. In one embodiment, the microfabricated particles of the invention are referred to as eligotropic, meaning that directional characteristics of the particles are selected to impart desired properties to a matrix or composite material that include the particles.

Microfabrication technology may be used to fabricate the particles that will allow for tremendous accuracy, precision, consistent replication, and flexibility in their construction on a micrometer scale or smaller. Microfabrication means that the particles are created as a multitude of objects of predetermined micro-scale dimensions in a combined manner to form an article. Each of the micro-scale objects are releasable from the article. In one embodiment, the article is well suited for various separation practices that result in the release of individual objects from the article. For purposes of the invention, “microfabrication” expressly excludes naturally occurring materials, solution phase created materials, and vapor phase created materials. The term “microfabricated” refers to particles that have been formed by microfabrication as defined herein.

In one embodiment, microfabricated particles may be fabricated into structures such as for example, crosses dumbbells, springs, coils, combs, auxetic structures, and interlocking geometries in the size range of microns to millimeters. Microfabricated particles may be built with structures specified by engineering designs. Furthermore, microfabricated particles are not limited to a single structure. One may construct microfabricated particles with multifunctional attributes or mix different microfabricated particles into the same matrix for different effects.

After fabrication, microfabricated particles may be mixed into a matrix to produce reinforced composites.

### BRIEF DESCRIPTION OF DRAWINGS

FIG. 1 is an image of a matrix embodying microfabricated particles at fifty times magnification;

FIG. 2 depicts various structures exemplifying microfabricated particles of the present invention;

FIG. 3 is an illustration of one multiple step process suitable for producing microfabricated particles useful in the present invention;

FIG. 4 is an illustration of a roll to roll process used in creating microfabricated particles;

FIG. 5 is an illustration of another embodiment of a roll to roll process for creating microfabricated particles; and

FIG. 6 is an illustration of a roll to roll process for releasing microfabricated particles from a web.

The above summary of the present invention is not intended to describe each disclosed embodiment or every implementation of the preset invention. The detailed description that follows more particularly exemplifies illustrative embodiments.

### DETAILED DESCRIPTION

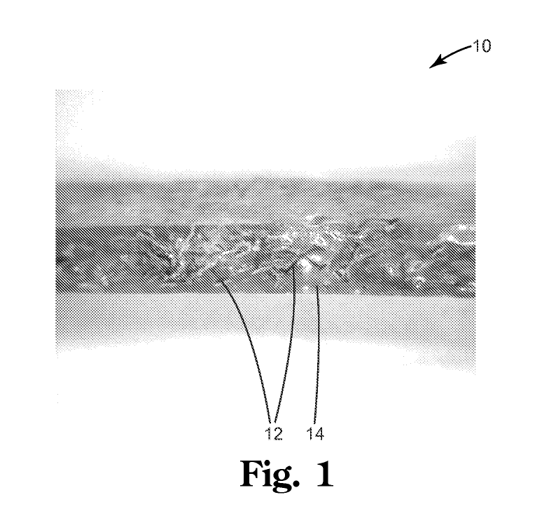

The composite reinforcement technology of the present invention encompasses microfabricated particles dispersed throughout a matrix. A microfabricated particle is a microfabricated object disperseable in a matrix wherein the object is of a predetermined design encompassing structure and composition. The microfabricated particle is included to impart a desired physical characteristic to the resulting composite. In one embodiment, the microfabricated particles are eligotropic, meaning that directional characteristics of the particles are selected to impart desired properties to a matrix or composite material that include the particles. FIG. 1 depicts the general application of composite 10 comprising microfabricated particles 12 dispersed throughout a polymeric matrix 14.

The matrix of the present invention may include various materials that can accept microfabricated particles. For example, the matrix may include polymeric materials, ceramic materials, cementitious materials, metals, alloys or combinations thereof. In certain embodiments, the matrix is one or more of a thermoset polymer or a thermoplastic polymer. In one embodiment, the matrix may include polymer selected, from aromatic poly amide (aramid), ultra-high molecular weight polyethylene (UHMWPE), poly-p-phenylenebenzobisoxazole (PBO)), polyethylene, polystyrene, polymethylmethacrylate (PMMA), polyacrylate, polyphenylene sulfide (PPS), polyphenylene oxide (PPO), polypropylene, polyarytetheretherketone (PEEK), nylon, polyvinylchloride (PVC, acrylonitrile butadiene styrene (ABS), polycarbonate (PC), polyethylene terephthalate (PET), or combinations thereof. Additional non-limiting examples of thermoset polymers suitable for use in the present invention include epoxies, urethanes, silicone rubbers, vulcanized rabbets, polyimide, melamine-formaldehyde resins, urea-formaldehyde resins, and phenol-formaldehyde resins. The matrix may include a range from about 10 to about 99 weight percent of the composite.

According to the present invention, the microfabricated particle is added to the matrix to develop the composite. The microfabricated particle is constructed from one or more materials using microfabrication practices detailed further below in this description. The one or more materials may include polymeric materials, gels, metals, semiconductors, glass, ceramic, inorganic films, or combinations thereof. Metals may include, for example, aluminum, silver, gold, platinum, iron, cobalt, tungsten, titanium, copper, zinc, tin, molybdenum and nickel. Non-limiting examples of inorganic films may include silicon dioxide, silicon nitride, carbon, aluminum oxide, and zinc oxide. Non-limiting examples of polymers may include polyimide, polyacrylate, polystryrene, polyvinyl alcohol, polyhydroxystyrene, polymethylmethacrylate, polysiloxane, polysilsesquioxane, melamine, or cresol-formaldehyde based polymers. In one embodiment, the polymeric based microfabricated particle is cross-linked.

The structure, size, porosity, or surface characteristics of the microfabricated particle may all vary in order to achieve desirable physical characteristics in the resulting composite. Additionally, the microfabricated particles may be designed to interact with each other, thereby further enhancing the physical characteristics of the composite. Mechanical, electrical or chemical interaction are three exemplary forms of such interaction. Specific non-limiting examples include (i) comb-like microfabricated particles having at least some tines that mesh with each other in the composite, (ii) microfabricated particles capable of self-assembly into cooperative structures or networks, (iii) chemical surface modification of the microfabricated particles that may include hydrophilic or hydrophobic construction or treatment of the particles, and (iv) integration of magnetic or electrically active materials into the microfabricated particles. In one embodiment, the microfabricated particles have a general size ranging from 0.1 to 5000 microns. The microfabricated particles are generally added to the matrix in an amount ranging from about greater than zero to about 80 weight percent.

The microfabricated particle may be designed or selected to impart various desirable properties to the resulting composite. For example, thermal properties, mechanical properties, electrical properties properties, magnetic properties, or combinations thereof may all be beneficially affected by the inclusion of a microfabricated particle in the matrix.

Structured microfabricated particles may be designed to improve particular mechanical properties. For example, to improve the elastic properties of a material, one of ordinary skill in the art may consider incorporating microfabricated particles with spring-like or coiled structures that elongate under stress. Of particular interest to armor applications is the ability to dampen and dissipate impact forces along a dimensional axis and from particle to particle within the composite. One embodiment may include collapsible structures that crush under impact, absorbing energy from collision. Although strong under tensile deformation, conventional fiber reinforced composites often fail under compression due to kinking. Microfabricated particles designed with cross structures could impart increased stiffness in the axis perpendicular to fiber alignment, thus improving compressive strength.

Auxetic structures are a form of microfabricated particles capable of improving impact resistance. An auxetic material exhibits the unusual behavior of a negative Poisson's ratio. Under such behavior, the cross-section of the material increases as the material is deformed under a tensile load. This unusual behavior is of significant interest to high impact strength applications because it represents a path by which energy may be dissipated between particles and in the direction perpendicular to the primary axis.

Certain embodiments may include structures that work in combination with the matrix to enable uniform electrical or thermal properties of the composite. For example, a matrix may contain microfabricated particles comprising electrically or thermally conductive materials shaped to provide multidirectional reinforcement, modification or conductivity.

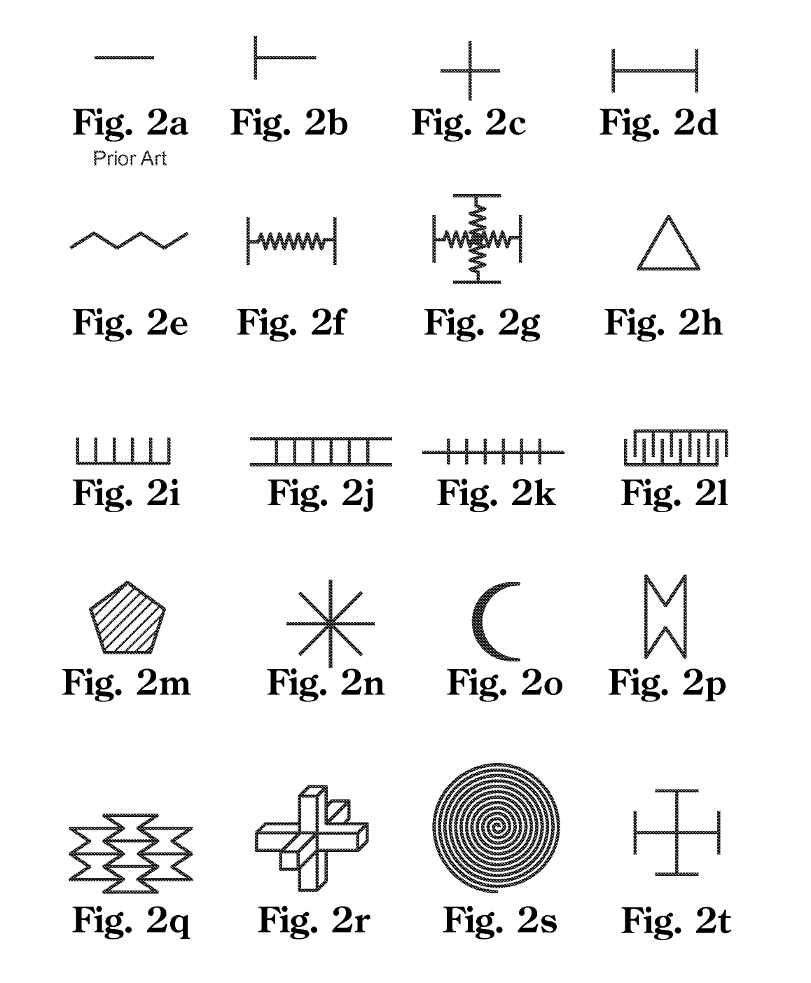

FIG. 2(a) is an illustration of standard fibers or filament articles that are conventionally employed as fillers in polymeric matrices. Typically, structures such as FIG. 2(a) offer anisotropic properties. FIGS. 2(b)-(t) depict several non-limiting examples of microfabricated particles suitable for applications within the context of the present invention. The embodiments of FIG. 2(b)-(t) through 2(r) are all embodiments that can enhance or improve physical characteristics in selected matrix applications. The specific structures are described as follows: FIG. 2(a) prior art fiber, FIG. 2(b) tee, FIG. 2(c) cross, FIG. 2(d) I-beam, FIG. 2(e) askew, FIG. 2(f) spring, FIG. 2(g) two dimensional spring, FIG. 2(h) open polygon, FIG. 2(i) comb, FIG. 2(j) ladder structure, FIG. 2(k) branched or segmented structure, FIG. 2(l) interlocking structures, FIG. 2(m) filled polygon, FIG. 2(n) starburst, FIG. 2(o) crescent, FIG. 2(p) auxetic structure, FIG. 2(q) auxetic network, FIG. 2(r) three dimensional crossbar, FIG. 2(s) spiral structures, and FIG. 2(t) T-headed cross. Those of ordinary skill in the art are capable of selecting one or more structures to achieve a desired end property for the resulting composite material.

In an alternative embodiment, the microfabricated particle may be designed to include auxiliary items such as, for example, sensors, encapsulated materials, release structures, electronics, tagants, optical components, or combinations thereof.

Manufacturing of the microfabricated particles may be accomplished through various conventional processes. Non-limiting examples for creating the microfabricated particles may include photolithography, electron beam lithography, ion beam lithography, interference lithography, imprint lithography, soft lithography, stamping, laser ablation, micromolding, micromachining, coating, printing, stencil masking, or combinations of the noted techniques. Printing techniques for applying a coating solution onto a substrate to create a pattern of microfabricated particles include gravure printing, flexographic printing, screen printing, inkjet printing, off-set printing, and combinations thereof.

Substrates provide the platform to construct the microfabricated particles. Substrates may include articles suitable for either batch processing or continuous processing. Non-limiting examples of both include wafers, web, tow, film, or finite sheets. In one embodiment, the substrate is of indefinite length (a moving web) and the microfabricated particles are created either on the substrate or out of a layer of the substrate in manner that is often referred to by those of ordinary skill on the art as roll to roll processing. The substrate may also include one or more layers of materials. For example, the substrate may have a release layer to assist in the separation of the microfabricated particles from the substrate. Those of ordinary skill in the art recognize that the material of construction for desired microfabricated particles may be a layer, or layers, within the substrate or deposited onto the substrate.

Depending on the type of desired materials of construction for the microfabricated particles, the substrate may be selected to enable either subtractive processing or additive processing. Non-limiting examples of subtractive processing include etching or ablation. In one embodiment with multilayered substrates, etching at least one layer of the multilayer substrate enables formation of microfabricated particles. Non-limiting examples of additive processing include printing or coating.

After creation of the microfabricated particles on the substrate in accordance with the previously noted patterning techniques, the particles may be further conditioned prior to their release from the substrate. Conditioning may include drying, curing, developing, washing, coating, surface treating, dissolving or combinations thereof. Those of ordinary skill in the art are capable of selecting the appropriate conditioning steps to address the selected materials used to form the microfabricated particles.

The microfabricated particles are subsequently separated or released from the substrate. The web and microfabricated particles nay then be washed after etching and then released in a solution bath. The microfabricated particles may be collected from the solution utilizing conventional separation practices.

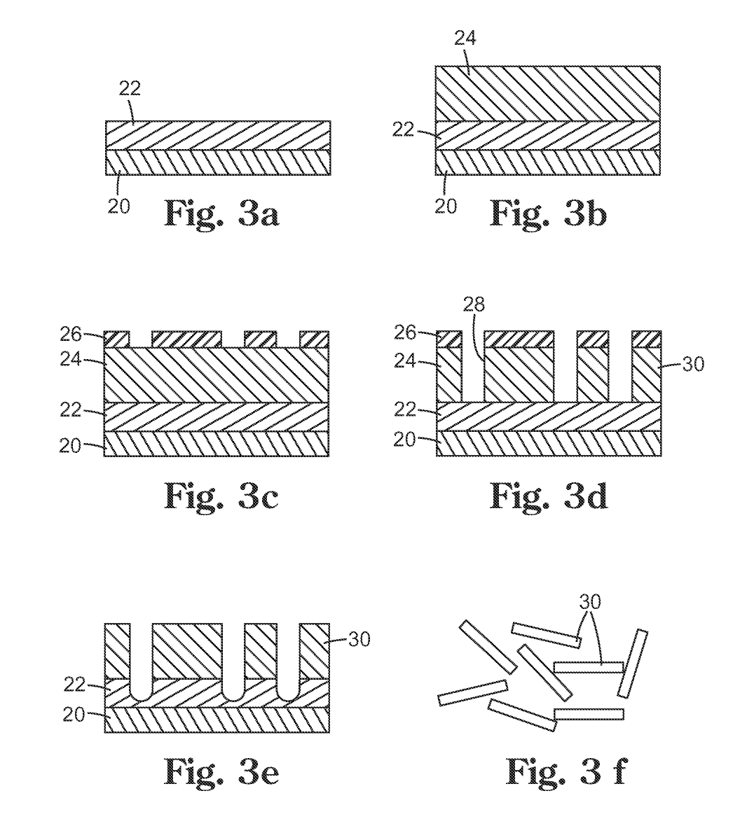

FIG. 3 is a non-limiting illustration of one solution-based process for creating microfabricated particles. In FIG. 3(a) a release layer 22 is deposited onto a substrate 20. The release layer 22 may optionally be incorporated into the substrate 20. The release layer 22 may be a soluble film, an adhesive film, or a magnetic film. The deposition of the particle layer 24 embodying the intended microfabricated particle is illustrated in FIG. 3(b). FIG. 3(c) depicts the patterning through the application of a pattern structure 26. FIG. 3(d) shows the pattern transfer by partial removal of the particle layer 24 creating voids 28. Dissolution of the release layer 22 is illustrated in FIG. 3(e) thereby creating the microfabricated particles 30 shown in FIG. 3(f). The microfabricated particles may then be collected and recovered from the solution for further processing.

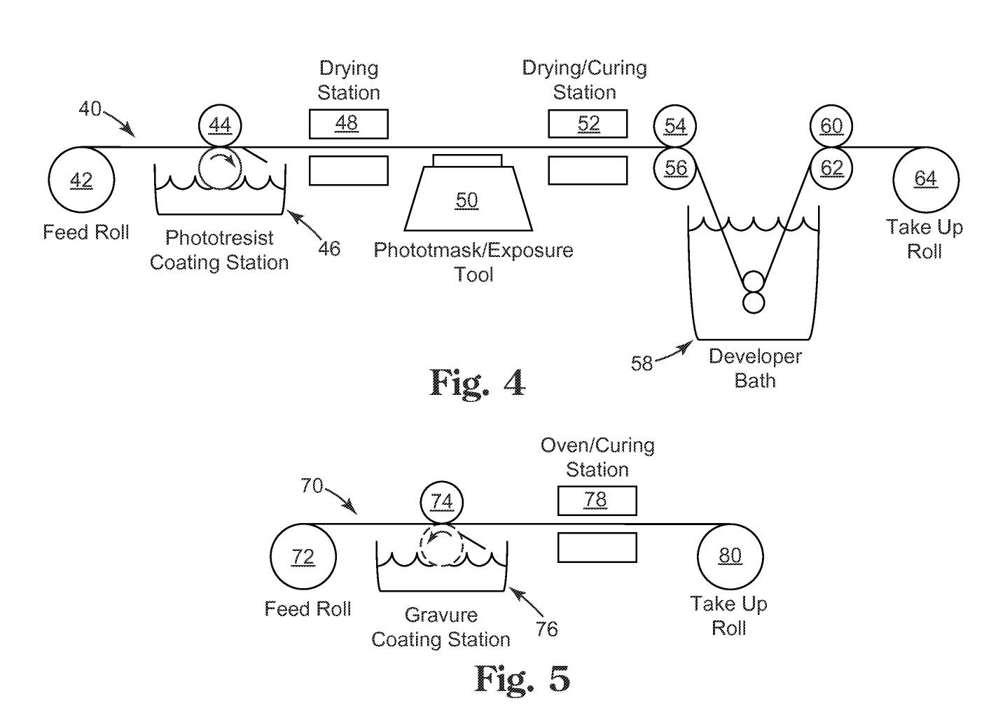

FIGS. 4 and 5 depict other embodiments involving a substrate of indefinite length. The non-limiting example illustrated in FIG. 4, demonstrates the creation of microfabricated particles on a moving web 40. The web 40 is taken from feed roll 42 through a nip roll 44 and photoresist coating station 46. The photoresist coating station 46 applies a photoresist coating onto web 40 that serves as a precursor to the finished microfabricated particles. The web 40 is then conveyed through a drying station 48, exposure station 50, and secondary drying/curing station 52 to finally form the microfabricated particles (not shown) on the web 40. The exposure may include subjecting the photoresist to electromagnetic radiation through a photomask. The photoresist may include either a positive or negative tone chemistry. Those of ordinary skill in the art recognize that the drying station may comprise various conventional drying techniques, for example, drying ovens, air knives, heaters, or radiation. Additional drying practices may include condensation drying units such as those disclosed in U.S. Pat. No. 5,581,905, herein incorporated by reference m its entirety. The web 40 containing the microfabricated particles is then conveyed through rollers 54, 56 and a developer bath 58 to selectively dissolve one tone of the photoresist. The web 40 exits the developer bath 58 through rollers 60, 62 and onto a take up roll 64.

FIG. 5 is a non-limiting illustration of another process suitable for creating microfabricated particles. The web 70 is conveyed from the feed roll 72 through nip roll 74 and gravure coating station 76. The gravure coating station 76 applies a coating solution onto web 70 to create a pattern that serves as a precursor to the finished microfabricated particles. The web 70 is then conveyed through a conventional drying station 78 and onto a take up roll 80. Those of ordinary skill in the art recognize that coating applications may be employed with either subtractive processing or additive processing.

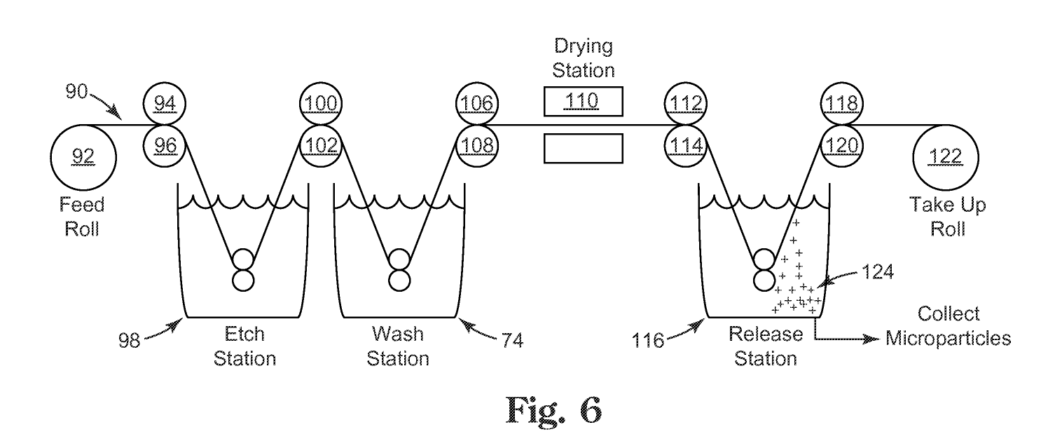

The release of the microfabricated particles from the web may be accomplished by several methods depending on the application of patterning method employed to create the microfabricated particle. FIG. 6 depicts one embodiment for etching and releasing the microfabricated particles from a web. The web 90 possessing microfabricated particles on the surface is conveyed from feed roll 92 through rollers 94, 96 and through etching station 98. From the etching bath 98, the web travels through rollers 100, 102 and through a washing station 104 to remove any etching solution. The web 90 is then conveyed through rollers 106, 108 and through a conventional drying station 110. The microfabricated particles remain on the surface of the web 90 until they are released in release bath 116. The web is conveyed into the release bath 116 by rollers 112, 114 and out of the release station 116 by rollers 118, 120 and onto take up roll 122. The microfabricated particles 124 are collected from the release bath 116 and separated from solution (not shown).

Conventional composite generation processes may be utilized to disperse one or more forms of microfabricated particles within a matrix. Suitable processes may include, for example, solution mixing, extrusion, injection molding, melt mixing, dry mixing, casting, or fiber spinning. Those skilled in the art are capable of selecting an appropriate process depending upon materials and end use applications.

In a further embodiment, microfabricated particles are released from the substrate of indefinite length, such as a carrier web by melting. A carrier web is chosen with a melting temperature that is below the melting or decomposition temperature of the microfabricated particles. When subjected to a temperature at, or in excess of, its melting temperature, the carrier web melts. Microfabricated particles are constructed from materials that maintain thermal stability at this temperature. Microfabricated particles release from the carrier web as the carrier web melts, allowing the microfabricated particles to be freely dispersed into the matrix. In one embodiment, microfabricated particles attached to a thermoplastic carrier web are fed into a mixing device, such as an extruder or melt mixer, operating at a temperature at, or above, the melting point of the carrier web with one or more matrices. In this embodiment, the released microfabricated particles disperse into the matrix.

Microfabricated particles may be further modified on their surfaces after construction by conventional processes. Surface modification can be performed while the particles remain attached to the carrier web, or after release of the microfabricated particles. Surface modification techniques, such as silanation, are well known methods for controlling the interfacial bonding between dissimilar materials for the purposes of promoting compatibilization. In one embodiment, the surface modification layer is deposited onto at least a portion of the surface of the microfabricated particle by silanation. The silination may occur in a suspension of microfabricated particles after release from the carrier web. In another embodiment, the silination process is applied from a liquid brought into contact with the microfabricated particles attached to a carrier web. Those of ordinary skill in the art are capable of identifying appropriate surface modifiers to address an intended application.

Conventionally recognized additives may also be included in the composite material. Non-limiting examples of conventional additives include antioxidants, light stabilizers, fibers, fillers, blowing agents, foaming additives, antiblocking agents, heat stabilizers, impact modifiers, biocides, plasticizers, tackifiers, colorants, processing aids, lubricants, coupling agents, and pigments. in an alternative embodiment, compatiblizing agents may be added to the composite. The additives may be incorporated into the composition in the form of powders, pellets, granules, or in any other form. The amount and type of conventional additives in the composition may vary depending upon the matrix and the desired physical properties of the finished composition. In one embodiment the microfabricated particles may interact with one or more of fillers and additives present in the matrix. Those skilled in the art are capable of selecting appropriate amounts and types of additives to match with a specific matrix in order to achieve desired physical properties of the finished material.

The resulting articles produced by the inventive composite exhibit improved physical characteristics. Such physical characteristics may include modulus, strength, toughness, elongation, impact resistance, reduction of anisotropy, thermal conductivity, electrical conductivity or combinations thereof.

The composites created through the utilization of the microfabricated particles may be employed in various applications and industries. For example, the composites of this invention are suitable for manufacturing articles in the construction, electronics, medical, aerospace, consumer goods and automotive industries. Articles incorporating the microfabricated particles may include: molded architectural products, forms, automotive parts, building components, household articles, biomedical devices, aerospace components, or electronic hard goods.

### EXAMPLES

### Example 1

### Construction of a Film Stack

A multilayer stack of materials was assembled for use in the construction of microfabricated microparticles. A 30.5 m roll of 0.01 cm thick foil of aluminum alloy 1235-0 was laminated on one side to a commercial polyethylene terephthalate polyester film (Fasson® 1 Mil Clear Print, product specification #77844) of 0.0025 cm thickness. The polyester film was coated with a pressure sensitive acrylic adhesive, which served as the bond between the aluminum alloy and the polyethylene terephthalate. In this construction, the aluminum layer was the substrate for the intended fabrication of microparticles, the polyethylene terephthalate film served as the carrier web, and the acrylic pressure sensitive adhesive was the release layer.

### Example 2

### Patterning of Microparticles by Photolithography

The substrate prepared according to Example 1 was processed by photolithographic patterning to produce shaped microparticles. A master photomask was produced containing a dense pattern of a multitude of microparticles shaped as T-headed crosses. The dimensions of the T-headed crosses were generally 2 mm by 2 mm with spires in the range of 0.2 mm. Conventional photomask fabrication processes were used to produce the chrome-on-glass photomask. The substrate was cut into four inch by four inch square sections. The substrate was baked on a hotplate at 205° C. for 5 minutes to dehydrate the surface of water, then exposed to a vapor of hexamethyldisilazane (HMDS) to promote adhesion of a photoresist film. A 2.0 μm thick film of photoresist (Microposit S1813, Rohm & Haas Electronic Materials) was spin coated onto the aluminum surface of the substrate. The coated substrate was subsequently baked on a hotplate for 60 seconds at 115° C. The coated substrate was exposed to broadband ultraviolet light for 10 seconds through the patterned photomask using a Karl Suss MJB-3 contact aligner exposure tool. The patterned image was developed from the photoresist film by selective dissolution of the exposed regions in a 0.25N solution of tetramethyl ammonium hydroxide in water. The patterned substrate was rinsed with water and dried in air. inspection by an optical microscope verified the formation of a fully developed, high contrast T-headed cross pattern in photoresist.

### Example 3

### Patterning of Microparticles by Ink-Jet Printing

The substrate prepared according to Example 1 was processed by inkjet printing to pattern the surface with shaped microparticles. A commercial ink-jet printer (PPSI High Speed Etch Resist Ink-jet Printer, Prototype & Production Systems, Inc.) was used to print patterns of T-headed crosses on a dense matrix with an etch resistant ink. The pattern was input into the printer via a bitmap image. The substrate was cut into 10.16 cm by 35.56 cm sheets. Printing was optimized for ink delivery to produce a robust pattern matching the input particle structure. After printing of the resist onto the aluminum surface of the substrate, the resist was cured with ultraviolet light by a broadband lamp for thirty seconds. Inspection by an optical microscope verified continuous coverage of the UV-cured ink over the pattern of the microparticle.

### Example 4

### Etching Using Concentrated Phosphoric Acid

The patterned substrate according to Example 2 was etched in an aqueous solution of concentrated phosphoric, acetic, and nitric acids sold as a Type A Aluminum Etchant, from the Transene Company, Inc., Danvers, Mass. The etchant solution was heated to 50° C. for an etch rate of aluminum of approximately 0.6 μm per minute. Etching was conducted until unmasked regions were completely dissolved. Etching removed aluminum that was not masked by photoresist, producing a pattern of isolated microparticles attached to the polyethylene terephthalate carrier web.

### Example 5

### Etching Using Copper Sulfate

The patterned substrate according to Example 3 was etched in an aqueous solution of copper sulfate. The etch solution was prepared from 50 grams of copper (II) sulfate, 12.5 grams of sodium chloride, and sufficient water to bring the solution volume to 500 mL. The patterned substrate was cut into sections 10.2 cm by 15.2 cm for etching at room temperature. Etching was conducted until unmasked regions were completely dissolved. During etching, a loose dark brown sediment formed on the surface of aluminum from the reaction products of the chemical etch, and was removed by gentile agitation and scraping of the surface. Etching removed aluminum that was not masked by photoresist, producing a pattern of isolated microfabricated particles attached to the polyethylene terephthalate carrier web.

### Example 6

### Electrolytic Etching to Release Microfabricated Particles

A 1000 mL aqueous solution consisting of 150 g of NaCl and 30 g of citric acid was prepared in a lab scale plastic beaker. A Pyrex square baking dish was set up next to an expandable platform and a Mastech Direct Current Power Supply HY3030E. An aluminum wire mesh was secured to the edges of the baking dish using binder clips, and a 1 mm diameter hole was cut into the mesh. An insulated copper wire, cut to expose the ends, was positioned through the hole in the wire mesh, clamped with an alligator clip to the exposed copper at the top to act as the anode, and secured to the expandable platform. The cathode was alligator clipped to the wire mesh at the edge of the baking dish. 750 mL of the aqueous solution was then added to the baking dish. The lithographic aluminum sample from Example 2 was placed into the aqueous solution in the baking dish. The copper wire was in contact with the aluminum surface and that the sample did not touch the wire mesh. The two leads, cathode and anode, were connected to the power supply. The power supply was operated at a constant voltage of 3 V and a current fluctuating around 10 A. The sample was etched for twenty minutes, during which tune aluminum in the unmasked regions was completely removed. After removal of sufficient aluminum to isolate particles, the particles were released from the carrier web. After the etching period, the solution was subjected to vacuum filtration, using an aspirator and a Buchner funnel. The filtrate was washed with water, and the microfabricated particles were collected in a 236.6 ml jar.

### Example 7

### Release of Particles

Patterned microparticles, according to Example 5, were removed from the polyethylene terephthalate carrier web by dissolution of the release layer provided by the acrylic pressure sensitive adhesive. Acetone was used to dissolve the release layer. Microparticles were separated from the web, collected, and separated from solution by filtration.

### Example 8

### Composite Fabrication

A 30 g sample of both 20 durometer parts A and B of Elastosil 3003 silicone rubber from Wacker Chemie AG were placed into a plastic cup, ensuring that the two types of silicone did not touch, avoiding a premature polymerization reaction. A 17.5 g sample of the microfabricated particles from Example 7 was added to the plastic cup containing the silicone and hand-mixed using a stainless steel spatula. A 15.24 cm by 15.24 cm by 2 mm thick metal frame was set on a sheet of aluminum and lightly coated with a non-stick coating. The microfabricated particle and silicone mixture was placed in the center of the metal frame, covered with another sheet of aluminum, and placed into a Dake hot press for five minutes with a pressure of 5 tons and plate temperatures of 165.6° C.

### Example 9

### Formation of a Composite by Thermoplastic Extrusion

Microparticles produced according to Example 5 were formed into composites in a polyolefin elastomer (Engage 8450, Dow Chemical) using a 1.9 cm single screw extruder (C.W. Brabender) at 150° C. For producing composites in this manner, microparticles were left attached to the polyethylene terephthalate carrier and fed into the extruder feeder in 2.54 cm wide strips with pellets of resin. Within the extruder the carrier web melts, releasing particles for mixing with the polyolefin. The thermoplastic composite was extruded through a 0.32 cm strand die. Visual inspection verified the mixing of particles into the composite.

From the above disclosure of the general principles of the present invention and the preceding detailed description, those skilled in this art will readily comprehend the various modifications to which the present invention is susceptible. Therefore, the scope of the invention should be limited only by the following claims and equivalents thereof.

1. A composition comprising a matrix and a plurality of microfabricated particles.

2. A composition according to claim 1, wherein the microfabricated particles are constructed from one or more materials.

3. A composition according to claim 2, wherein the one or more materials include polymeric materials, gels, metals, semiconductors, glass, ceramic, inorganic films, or combinations thereof.

4. A composition according to claim 1, wherein the microfabricated particles impart thermal properties, mechanical properties, electrical properties, chemical properties, magnetic properties, or combinations thereof to the composition.

5. A composition according to claim 1, further comprising a compatiblization agent.

6. A composition according to claim 1, wherein the matrix is selected from polymeric materials, ceramic materials, cementitious materials, metals, alloys or combinations thereof.

7. A composition according to claim 1, further comprising a surface coating on at least a portion of the microfabricated particle.

8. A composition according to claim 1, wherein the microfabricated particle includes sensors, devices, encapsulated materials, release structures, electronics, tagants, optical components, or combinations thereof.

9. A composition according to claim 1, wherein the microfabricated particle is manufactured by photolithography, electron beam lithography, ion beam lithography, interference lithography, imprint lithography, soft lithography, stamping, laser ablation, micromolding, micromachining, printing, coating, stencil masking or combinations thereof.

10. A composition according to claim 1, wherein the matrix is one or more of a thermoset polymer or thermoplastic polymer.

11. A method comprising forming a composite having a matrix and a plurality of microfabricated particles.

12. A method according to claim 11, wherein the composite is formed by solution mixing, extrusion, injection molding, melt mixing, dry mixing, casting, or fiber spinning.

13. A method according to claim 11, wherein the matrix is selected from polymeric materials, ceramic materials, cementitious materials, metals, alloys or combinations thereof.

14. A method according to claim 11, wherein the microfabricated particle is constructed from one or more materials or includes one or more particle structures.

15. A method according to claim 14, wherein the one or more materials include polymeric materials, gels, metals, semiconductors, glass, ceramic, inorganic films, or combinations thereof.

16. A method comprising creating a plurality of microfabricated particles on or within a substrate of indefinite length, wherein the plurality of microfabricated particles are releasably attached to the substrate.

17. A method according to claim 16, wherein the substrate is a multilayered film and at least one layer of the film is suitable for creating microfabricated particles.

18. A method according to claim 16, wherein the plurality of microfabricated particles are created by subtractive processing or additive processing.

19. A method according to claim 16, wherein the substrate includes a release layer to facilitate removal and collection of microfabricated particles.

20. A method according to claim 16, further comprising conditioning the plurality of microfabricated particles prior to releasing microfabricated particles from the substrate.

21. A method according to claim 20, wherein the conditioning includes drying, curing, developing, coating, surface treating, dissolving, washing or combinations thereof.

22. A method according to claim 16, further comprising etching at least one layer of a multilayer substrate to enable formation of microfabricated particles.

23. A method according to claim 16, further comprising releasing the plurality of microfabricated particles from the substrate.

24. A method according to claim 23, wherein releasing of the microfabricated particles from the substrate of indefinite length occurs during melt processing of the microfabricated particles with a matrix.

25. A method according to claim 24, wherein the substrate of indefinite length is a carrier web that possesses a melting point at or below the melt processing temperature of the matrix.

26. (canceled)

27. A method according to claim 16, wherein creating the plurality of microfabricated particles includes photolithography, electron beam lithography, ion beam lithography, interference lithography, imprint lithography, soft lithography, stamping, laser ablation, micromolding, micromachining, coating, printing, stencil masking and combinations thereof.

28. (canceled)

29. A method according to claim 16, wherein the plurality of microfabricated particles are constructed of one or more materials of polymeric materials, gels, metals, semiconductors, glass, ceramic, inorganic films, and combinations thereof.

30. An article comprising microfabricated particles releasably attached on a substrate of indefinite length.

31. (canceled)

32. A composition according to claim 1, wherein the microfabricated particles interact with each other.

33. A composition according to claim 32, wherein the interaction is mechanical interaction, electrical interaction, or chemical interaction.

34. (canceled)
